(19) United States
(12) Patent Application Publication
(10) Pub. No.: US 2010/0061060 A1
(43) Pub. Date: Mar. 11, 2010

(54) HEAT-DISSIPATING DEVICE

(75) Inventors: Ming-Wei TIEN, Taipei Hsien (TW); Yen-Yu Chao, Taipei Hsien (TW)

Correspondence Address: FOLEY AND LARDNER LLP;SUITE 500, 3000 K STREET NW, WASHINGTON, DC, 20007, US

(73) Assignee: WISTRON CORPORATION

(21) Appl. No.: 12/427,918

(22) Filed: Apr. 22, 2009

(30) Foreign Application Priority Data
Sep. 9, 2008 (TW) 097134546

(51) Int. Cl. H05K 7/20

(52) U.S. Cl. 361/697; 361/679.51; 361/703; 361/679.47

(57) ABSTRACT

A heat-dissipating device includes a heat sink, a heat-dissipating fan, and a first air guide hood. The heat sink includes a base, and a plurality of interconnected heat-dissipating fins provided on the base. Each adjacent pair of the heat-dissipating fins defines an air channel therebetween. The heat-dissipating fan is disposed at a rear side of the heat sink to provide a heat-dissipating air current to the heat sink such that the air current flows from the rear side of the heat sink through the air channels and out through a front side of the heat sink. The first air guide hood is disposed at one of left and right sides of the heat sink and is located in front of the heat-dissipating fan to guide a portion of the air current provided by the heat-dissipating fan to the outside through one side of the heat sink.

### CROSS-REFERENCE TO RELATED APPLICATION

This application claims priority of Taiwanese Application No. 097134546, filed on Sep. 9, 2008.

### BACKGROUND OF THE INVENTION

1. Field of the Invention

The invention relates to a heat-dissipating device, more particularly to an air guide configuration of a heat-dissipating device that is capable of changing the direction of flow of a heat-dissipating air current.

2. Description of the Related Art

Referring to FIGS. 1 and 2, a conventional heat-dissipating device 1 includes a heat sink 11, a securing frame 12, a heat-dissipating fan 13, and an air guide hood 14. The heat sink 11 includes a base 111 that is locked to a motherboard 21 via a locking mechanism 112, and that abuts against a top surface of a central processing unit 22 so as to dissipate the heat of the central processing unit 22. The heat sink 11 further includes a plurality of heat-conducting tubes 113 mounted on the base 111, and a plurality of heat-dissipating fins 114 arranged in a stack and disposed on the heat-conducting tubes 113. The heat-conducting tubes 113 are used to conduct heat from the base 111 to the heat-dissipating fins 114, and the heat is dissipated via the heat-dissipating fins 114. The heat-dissipating fan 13 is provided within the securing frame 12, and is assembled to the base 111 of the heat sink 11 via the securing frame 12 so as to provide a heat-dissipating air current to the heat sink 11.

When the heat-dissipating fan 13 is in operation, the air current flows into air channels 116 defined by the heat-dissipating fins 114 through an air inlet 115 at a rear side of the heat sink 11, and exits through an air outlet 117 at a front side of the heat sink 11, thereby cooling the heat-conducting tubes 113 and the heat-dissipating fins 114. In addition, the heat-dissipating air current from the heat-dissipating fan 13 can be guided to flow downwardly by means of the air guide hood 14 provided at a front side of the securing frame 12 and located below the heat-dissipating fins 114, so as to dissipate the heat of a heat-generating electronic component 23 provided at a front side of the central processing unit 22. However, the air guide hood 14 of the conventional heat-dissipating device 1 can merely dissipate the heat of the heat-generating electronic component 23 at the front side of the central processing unit 22. Furthermore, the heat-dissipating device 1 is not additionally configured to have other air outlets and structures to adjust angles of air currents. Therefore, problem associated with the heat produced by heat-generating electronic components (not shown) at left and right sides of the heat-dissipating device 1 when they are in operation can not be solved.

Referring to FIG. 3, a heat sink 31 of another conventional heat-dissipating device 3 is provided with a heat-dissipating fan 32 at a top surface thereof. The heat sink 31 includes a base 311 provided with a plurality of heat-dissipating fins 312 that are angularly spaced apart from each other. Thus, a heat-dissipating air current provided to the heat sink 31 by a heat-dissipating fan 32 may flow in directions indicated by the arrows in the figure, and is discharged through outer peripheries of the heat-dissipating fins 312. However, the heat-dissipating device 3 can not direct the heat-dissipating air current to flow toward a specific direction or at a specific angle. Therefore, the heat of the other heat-generating electronic components can not be dissipated effectively.

### SUMMARY OF THE INVENTION

A primary object of the present invention is to provide a heat-dissipating device that can dissipate the heat of a central processing unit and the heat of heat-generating electronic components around the central processing unit.

The aforesaid object of the present invention and solutions to technical problems associated therewith are realized using the technical means described hereinbelow. The heat-dissipating device according to this invention includes a heat sink, a heat-dissipating fan, and a first air guide hood.

The heat sink includes a base, and a plurality of interconnected heat-dissipating fins provided on the base. Each adjacent pair of the heat-dissipating fins defines an air channel therebetween. The heat-dissipating fan is disposed at a rear side of the heat sink to provide a heat-dissipating air current to the heat sink such that the heat-dissipating air current flows from the rear side of the heat sink through the air channels and out through a front side of the heat sink. The first air guide hood is disposed at one of left and right sides of the heat sink and is located in front of the heat-dissipating fan to guide a portion of the heat-dissipating air current provided by the heat-dissipating fan to the outside through one of the left and right sides of the heat sink at which the first air guide hood is disposed.

The object of the present invention and the solutions to the technical problems associated therewith may be further realized using the following technical means.

In the aforesaid heat-dissipating device, the first air guide hood includes an upright first air guide plate extending slantingly forward and outward from one side of the heat sink which extends in a front-rear direction.

Thus, a portion of the heat-dissipating air current can be guided to the outside.

In the aforesaid heat-dissipating device, the first air guide hood further includes a plurality of second air guide plates extending slantingly downward from an outer surface of the first air guide plate. Thus, a portion of the heat-dissipating air current can be guided to a lower outside.

The aforesaid heat-dissipating device further includes a baffle plate disposed at the other one of the left and right sides of the heat sink and located in front of the heat-dissipating fan to guide a portion of the heat-dissipating air current to the outside through the other one of the left and right sides of the heat sink.

In the aforesaid heat-dissipating device, the heat sink further includes a heat-conducting member assembled to the base and disposed for mounting of the heat-dissipating fins thereto. The heat-dissipating device further includes a second air guide hood disposed below the heat-dissipating fins and including a third air guide plate located at a front end thereof and extending slantingly forward and downward. Thus, a portion of the heat-dissipating air current can be guided to a lower front side.

The aforesaid heat-dissipating device further includes a positioning frame assembled to the rear side of the heat sink. The heat-dissipating fan and the first air guide hood are respectively assembled to the positioning frame. The positioning frame includes two engaging slots respectively located in upper and lower sides thereof. The first air guide hood includes an engaging plate engaged between the engaging slots.

The heat-dissipating device according to this invention can change the direction of flow of a portion of the heat-dissipating air current provided by the heat-dissipating fan by virtue of the arrangement of the first and second air guide hoods and the baffle plate. Thus, the heat-dissipating device not only can dissipate the heat of the central processing unit, it can also dissipate the heat of the heat-generating electronic components and the memory around the central processing unit.

### BRIEF DESCRIPTION OF THE DRAWINGS

Other features and advantages of the present invention will become apparent in the following detailed description of the preferred embodiment with reference to the accompanying drawings, of which:

FIG. 1 is a front view of a conventional heat-dissipating device;

FIG. 2 is a right side view of the conventional heat-dissipating device;

FIG. 3 is a perspective view of another conventional heat-dissipating device;

FIG. 4 is a perspective view of a preferred embodiment of a heat-dissipating device according to this invention when mounted on a circuit board;

FIG. 5 is an exploded perspective view of the preferred embodiment of the heat-dissipating device according to this invention;

FIG. 6 is a top view of the preferred embodiment of the heat-dissipating device according to this invention when mounted on the circuit board, illustrating that a heat-dissipating air current can be guided by a first air guide hood and a baffle plate to dissipate the heat of a memory and heat-generating electronic components;

FIG. 7 is a front view of the preferred embodiment of the heat-dissipating device according to this invention when mounted on the circuit board, illustrating that the heat-dissipating air current can be guided by the first air guide hood and the baffle plate to dissipate the heat of the memory and the heat-generating electronic components;

FIG. 8 is a right side view of the preferred embodiment of the heat-dissipating device according to this invention when mounted on the circuit board, illustrating that the heat-dissipating air current can be guided by a second air guide hood to dissipate the heat of the heat-generating electronic components; and

FIG. 9 is a left side view of the preferred embodiment of the heat-dissipating device according to this invention when mounted on the circuit board, illustrating that the heat-dissipating air current can be guided by the second air guide hood to dissipate the heat of the heat-generating electronic components.

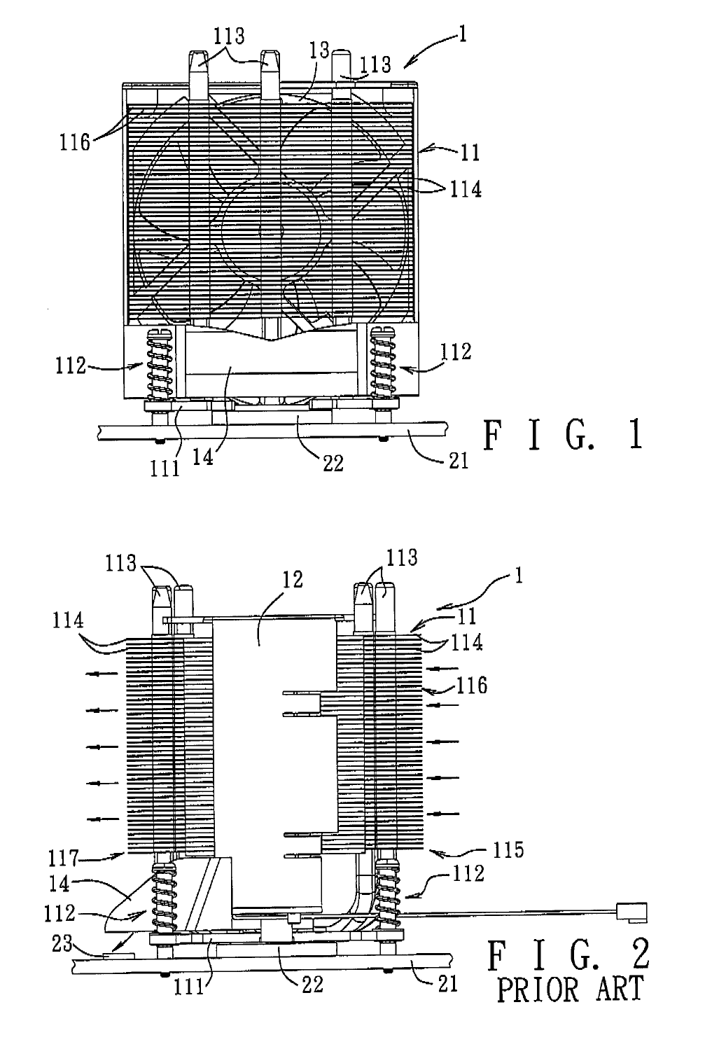

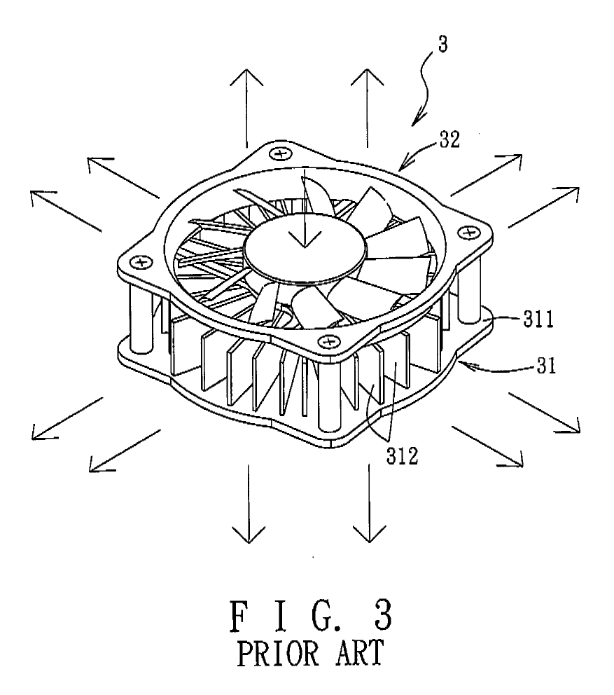

### DETAILED DESCRIPTION OF THE PREFERRED EMBODIMENT

Through a detailed description of the preferred embodiment, the technical means adopted to achieve the intended object and advantageous effects of the present invention should be better understood. However, the accompanying drawings are provided for reference and illustration only and should not be based upon to limit the scope of protection sought for the present invention.

Before the present invention is described in greater detail, it should be noted that like elements are denoted by the same reference numerals throughout the disclosure.

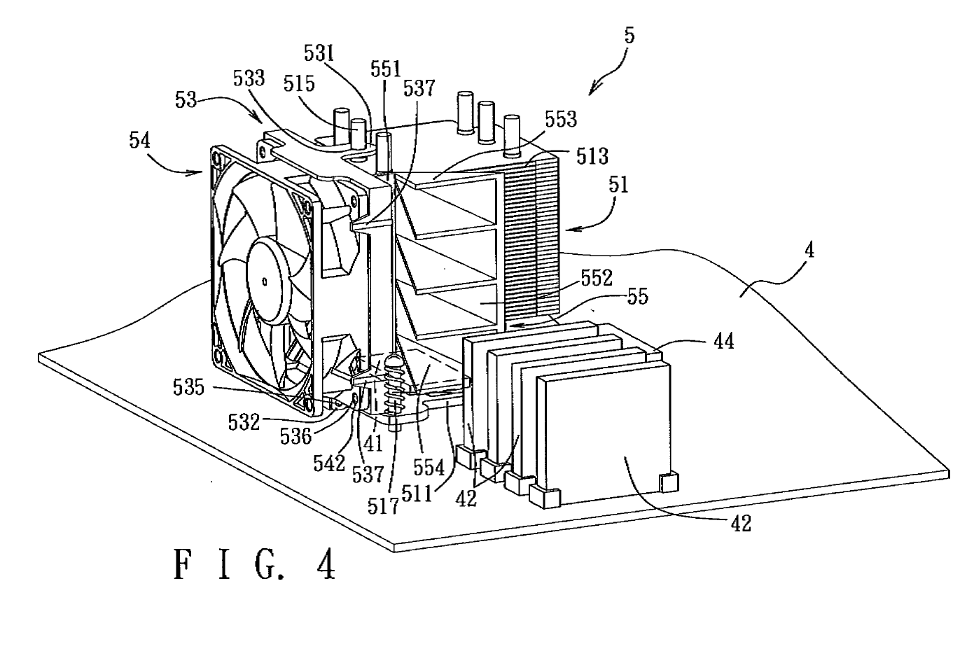

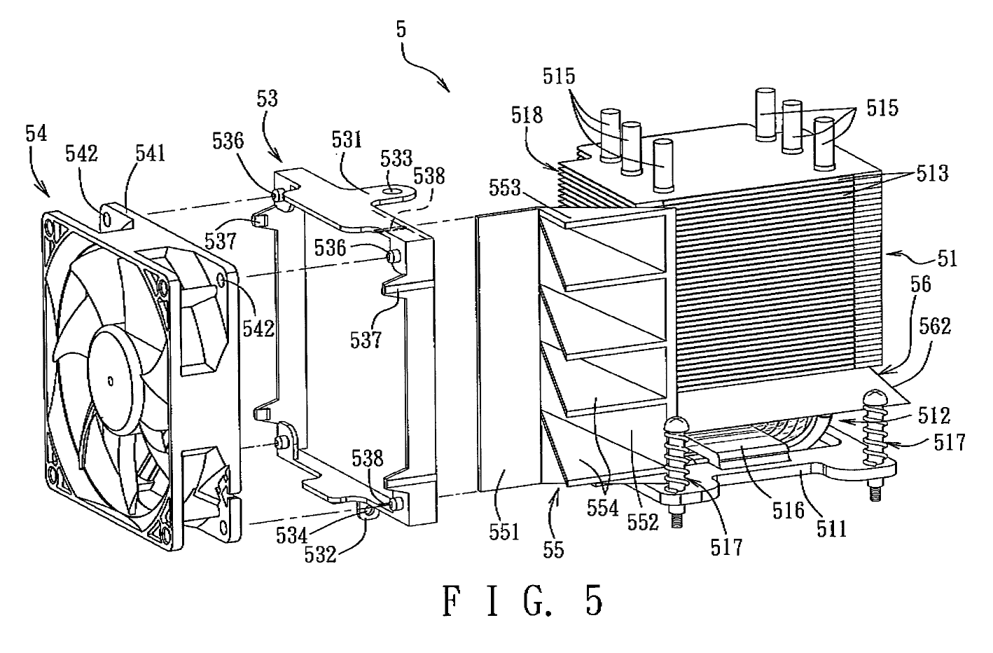

Referring to FIGS. 4 and 5, the preferred embodiment of a heat-dissipating device 5 according to this invention is mounted on a motherboard 4 to dissipate the heat of a central processing unit 41 on the motherboard 4 and heat-generating electronic components around the central processing unit 41. The heat-dissipating device 5 includes a heat sink 51, a positioning frame 53, a heat-dissipating fan 54, and a first air guide hood 55.

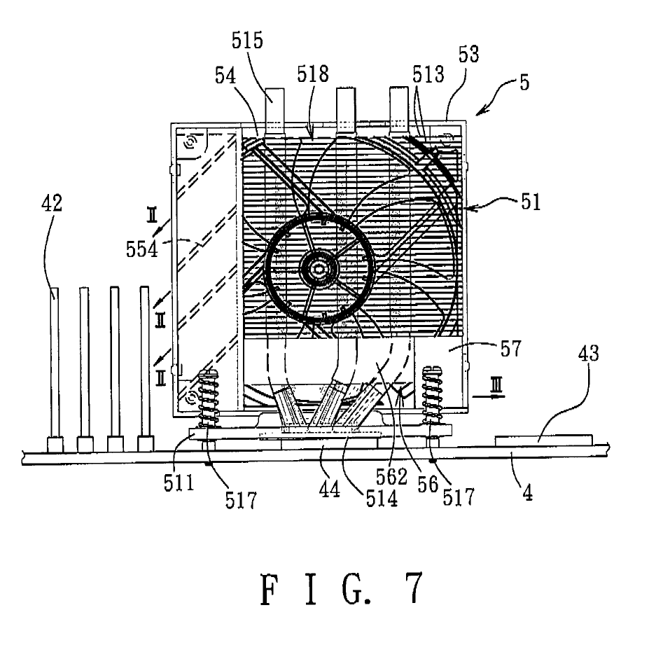

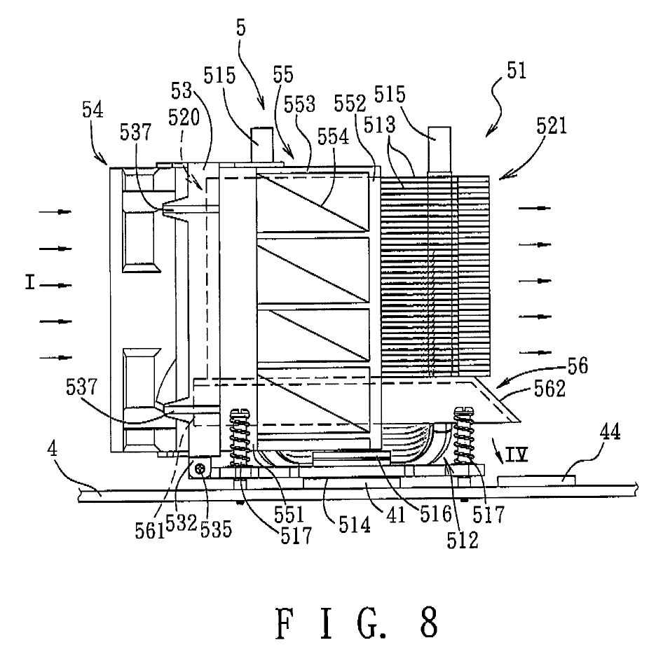

Referring to FIGS. 5, 6, 7, and 8, in the following description, the side of the heat-dissipating device 5 on which the heat sink 51 is located is referred to as a front side of the heat-dissipating device 5, and the side of the heat-dissipating device S on which the heat-dissipating fan 53 is located is referred to as a rear side of the heat-dissipating device 5. The heat sink 51 includes a base 511, a heat-conducting member 512, and a plurality of heat-dissipating fins 513. The base 511, the heat-conducting member 512, and the heat-dissipating fins 513 are made of materials which have good heat conductivity, e.g., copper, aluminum, etc. The heat-conducting member 512 includes a contacting portion 514 for abutting against the central processing unit 41 on the motherboard 4, and a plurality of heat-conducting tubes 515 extending upwardly from the contacting portion 514. The base 511 includes an abutting portion 516 protruding at a middle part thereof for abutting against the heat-conducting tubes 515, and is locked to the motherboard 4 via a locking mechanism 517, so that the contacting portion 514 of the heat-conducting member 512 abuts tightly against a top surface of the central processing unit 41. The heat-dissipating fins 513 are arranged in a stack and are fitted around the heat-conducting tubes 515 of the heat-conducting member 512. Each adjacent pair of the heat-dissipating fins 513 defines an air channel 518 therebetween which extends along a front-rear direction.

The positioning frame 53 includes a first protruding piece 531 projecting from a top face thereof, and two second protruding pieces 532 projecting from a bottom face thereof. The first protruding piece 531 is provided with a through hole 533. The second protruding pieces 531 are respectively provided with through holes 534 respectively corresponding in position to threaded holes 519 in a rear side of the base 511. The positioning frame 53 is assembled and secured to a rear side of the heat sink 51 by extending one of the heat-conducting tubes 515 of the heat sink 51 through the through hole 533 in the first protruding piece 531 and by extending bolts 535 respectively through the through holes 534 in the second protruding pieces 532 to be locked in the threaded holes 519 in the base 511. The heat-dissipating fan 54 is an axial type fan providing a heat-dissipating air current to the heat sink 51, and includes a frame 541, and a plurality of positioning holes 542 provided in the frame 541 and corresponding in position to studs 536 of the positioning frame 53. The heat-dissipating fan 54 is secured to the positioning frame 53 by extending the studs 536 of the positioning frame 53 respectively through the positioning holes 542 and by causing hooks 537 on left and right sides of the positioning frame 53 to engage the frame 541 of the heat-dissipating fan 54.

The first air guide hood 55 includes an upright engaging plate 551, an upright first air guide plate 552 extending slantingly forward and outward from a front end of the engaging plate 551, a top plate 553 extending horizontally and outwardly from a top end of the first air guide plate 552, and a plurality of second air guide plates 554 extending slantingly downward from an outer surface of the first air guide plate 552. The second air guide plates 554 are spaced apart from one another along a top-bottom direction. The first air guide hood 55 is assembled and secured to the positioning frame 53 by having upper and lower ends of the engaging plate 551 engaging upper and lower engaging slots 538 in the positioning frame 53. In this state, the first air guide hood 55 is located in front of the heat-dissipating fan 54 and at a right side of the heat-dissipating fins 513 of the heat sink 51. Thus, a portion of the heat-dissipating air current provided by the heat-dissipating fan 54 can be guided outwardly from the right side of the heat-dissipating fins 513. It is noted that the first air guide hood 55 can be integrally formed with the positioning frame 53 or can be screwably connected to the positioning frame 53. The manner of connection should not be limited to that disclosed in the preferred embodiment.

In addition, the heat-dissipating device 5 further includes a second air guide hood 56 disposed at a bottom end of the heat-dissipating fins 513, and a baffle plate 57 disposed at a left edge of the second air guide hood 56. The second air guide hood 56 includes an opening 561 formed in a rear end thereof, and a third air guide plate 562 located at a front end thereof and extending slantingly forward and downward. With the arrangement of the second air guide hood 56, a portion of the heat-dissipating air current provided by the heat-dissipating fan 54 can be guided to a front side of the base 511 of the heat sink 51. The arrangement of the baffle plate 57 permits a portion of the heat-dissipating air current provided by the heat-dissipating fan 54 to be guided to a left side of the heat sink 51.

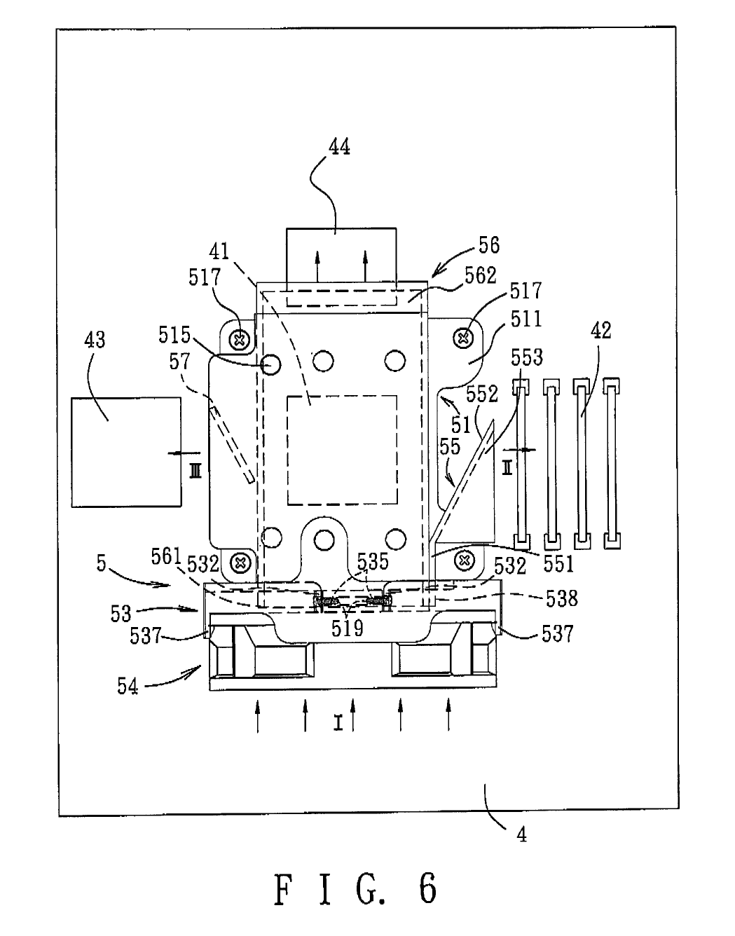

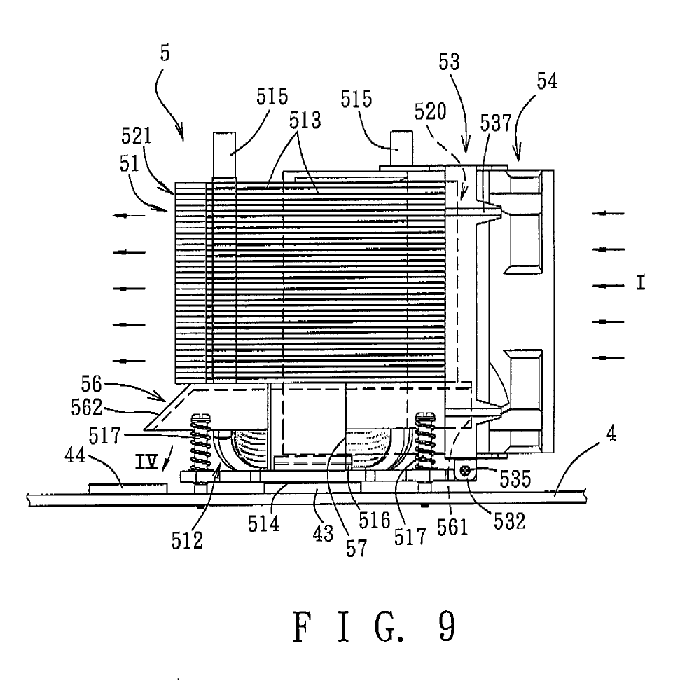

Referring to FIGS. 6, 7, 8, and 9, when the central processing unit 41 is in operation, the heat generated thereby is conducted to the heat-conducting tubes 515 via the contacting portion 514 of the heat-conducting member 512, and is further conducted to the heat-dissipating fins 513 via the heat-conducting tubes 515 for heat dissipation. At the same time, the heat-dissipating fan 54 provides a heat-dissipating air current flowing in a direction indicated by arrows (I) to the heat sink 51. A large portion of the heat-dissipating air current flows into the air channels 51 through an air inlet 520 at a rear side of the heat-dissipating fins 513, passes through the air channels 51B, and flows out through an air outlet 521 at a front side of the heat-dissipating fins 513, thereby cooling the heat-conducting tubes 515 and the heat-dissipating fins 513 and effectively guiding the heat out of the central processing unit 41.

Since the first and second air guide hoods 55, 56 and the baffle plate 57 are all disposed at a front side of the heat-dissipating fan 54 and are located on a flow path of the heat-dissipating air current, a portion of the heat-dissipating air current is guided by the first and second air guide plates 552, 554 of the first air guide hood 55 to flow out through a lower right side of the heat sink 51 along a direction indicated by arrows (II), thereby dissipating the heat of a memory 42 provided on the motherboard 4 and located at a right side of the central processing unit 41. Moreover, a portion of the heat-dissipating air current is guided by the baffle plate 57 to flow out through the left side of the heat sink 51 along a direction indicated by arrows (III), thereby dissipating the heat of a heat-generating electronic component 43 provided on the motherboard 4 and located at a left side of the central processing unit 41. Furthermore, a portion of the heat-dissipating air current flows into the second air guide hood 56 through the opening 561 of the second air guide hood 56, and is guided by the third air guide plate 562 to flow out through a lower front side of the heat sink 51 along a direction indicated by arrows (IV), thereby dissipating the heat of a heat-generating electronic component 44 provided on the motherboard 4 and located at a front side of the central processing unit 41. The flow direction of a portion of the heat-dissipating air current provided by the heat-dissipating fan 54 can be changed by the arrangement of the first and second air guide hoods 55, 56, and the baffle plate 57. Thus, the heat-dissipating device 5 not only can dissipate the heat of the central processing unit 41, it can also dissipate the heat of the heat-generating electronic components 43, 44 and the memory 42 around the central processing unit 41.

It should be mentioned that, in practical applications, the heat-dissipating device 5 may include two first air guide hoods 55 located respectively at the left and right sides of the heat-dissipating fins 513, or two baffle plates 57 located respectively at the left and right sides of the second air guide hood 56. The number of the first air guide hood 55 and the baffle plate 57 can be varied according to practical requirements, and should not be limited to the preferred embodiment of this invention, in which one first air guide hood 55 and one baffle plate 57 are used. Furthermore, the second air guide plates 554 of the first air guide hood 55 may be configured to be pivotally connected to the first air guide plate 552, so that the angles of the second air guide plates 554 can be adjusted according to the position of the memory 52 or the heat-generating electronic components 43, 44 so as to change the direction of flow of the heat-dissipating air current discharged from the first air guide hood 55.

In sum, the heat-dissipating device 5 of the preferred embodiment can change the direction of flow of a portion of the heat-dissipating air current provided by the heat-dissipating fan 54 by virtue of the arrangement of the first and second air guide hoods 55, 56 and the baffle plate 57. Thus, the heat-dissipating device 5 not only can dissipate the heat of the central processing unit 41, it can also dissipate the heat of the heat-generating electronic components 43, 44 and the memory 42 around the central processing unit 41.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements. In addition, it should be readily appreciated that any of the embodiments as described herein or any of the claims as appended hereto does not necessarily have to achieve all of the objects, advantages or features disclosed herein. Moreover, the title of the invention and the abstract of disclosure are provided herein to allow a searcher to quickly ascertain the subject matter of the technical disclosure of any patent issued on this application, and should not be relied upon to limit the scope of protection sought for this invention.

We claim:

1. A heat-dissipating device, comprising:
a heat sink including a base, and a plurality of interconnected heat-dissipating fins provided on said base, each adjacent pair of said heat-dissipating fins defining an air channel therebetween;
a heat-dissipating fan disposed at a rear side of said heat sink to provide a heat-dissipating air current to said heat sink such that said heat-dissipating air current flows from said rear side of said heat sink through said air channels and out through a front side of said heat sink; and
a first air guide hood disposed at one of left and right sides of said heat sink and located in front of said heat-dissipating fan to guide a portion of said heat-dissipating air current provided by said heat-dissipating fan to the outside through one of said left and right sides of said heat sink at which said first air guide hood is disposed.

2. The heat-dissipating device as claimed in claim 1, wherein said first air guide hood includes an upright first air guide plate extending slantingly forward and outward from one side of said heat sink which extends in a front-rear direction.

3. The heat-dissipating device as claimed in claim 2, wherein said first air guide hood further includes a plurality of second air guide plates extending slantingly downward from an outer surface of said first air guide plate.

4. The heat-dissipating device as claimed in claim 1, further comprising a baffle plate disposed at the other one of said left and right sides of said heat sink and located in front of said heat-dissipating fan to guide a portion of said heat-dissipating air current to the outside through the other one of said left and right sides of said heat sink.

5. The heat-dissipating device as claimed in claim 1, wherein said heat sink further includes a heat-conducting member assembled to said base and disposed for mounting of said heat-dissipating fins thereto, said heat-dissipating device further comprising a second air guide hood disposed below said heat-dissipating fins and including a third air guide plate located at a front end thereof and extending slantingly forward and downward.

6. The heat-dissipating device as claimed in claim 1, further comprising a positioning frame assembled to the rear side of said heat sink, said heat-dissipating fan and said first air guide hood being respectively assembled to said positioning frame.

7. The heat-dissipating device as claimed in claim 6, wherein said positioning frame includes two engaging slots respectively located in upper and lower sides thereof, said first air guide hood including an engaging plate engaged between said engaging slots.

8. The heat-dissipating device as claimed in claim 3, further comprising a baffle plate disposed at the other one of said left and right sides of said heat sink and located in front of said heat-dissipating fan to guide a portion of said heat-dissipating air current to the outside through the other one of said left and right sides of said heat sink.

9. The heat-dissipating device as claimed in claim 8, wherein said heat sink further includes a heat-conducting member assembled to said base and disposed for mounting of said heat-dissipating fins thereto, said heat-dissipating device further comprising a second air guide hood disposed below said heat-dissipating fins and including a third air guide plate located at a front end thereof and extending slantingly forward and downward.

10. The heat-dissipating device as claimed in claim 3, further comprising a positioning frame assembled to the rear side of said heat sink, said heat-dissipating fan and said first air guide hood being respectively assembled to said positioning frame.

11. The heat-dissipating device as claimed in claim 10, wherein said positioning frame includes two engaging slots respectively located in upper and lower sides thereof, said first air guide hood including an engaging plate engaged between said engaging slots.
